(19) United States
(12) Patent Application Publication
(10) Pub. No.: US 2003/0123234 A1
(43) Pub. Date: Jul. 3, 2003

(54) Printed wiring board having pads to solder circuit component, circuit module having the printed wiring board, and electronic apparatus equipped with the circuit module

(75) Inventor: Akihiko Happoya, Fussa-shi (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 10/233,465

(22) Filed: Sep. 4, 2002

(30) Foreign Application Priority Data
Dec. 28, 2001 (JP) 2001-401099

(51) Int. Cl. H05K 5/00; H05K 5/04; H05K 5/06

(52) U.S. Cl. 361/752

(57) ABSTRACT

A printed wiring board includes a substrate having a packaging surface and at least one pad mounted on the packaging surface. The pad has an area to solder a circuit component. At least one connection part is placed in the area of the pad. The connection part is electrically insulated from the pad and connected to a circuit electrically different from the pad.

### CROSS REFERENCE TO RELATED APPLICATIONS

This application is based upon and claims the benefit of priority from the prior Japanese Patent Application No. 2001-401099, filed Dec. 28, 2001, the entire contents of which are incorporated herein by reference.

### BACKGROUND OF THE INVENTION

1. Field of the Invention

The present invention relates to a printed wiring board having pads to solder a surface mount circuit component such as a bare chip, a circuit module with a circuit component soldered to the printed wiring board and an electronic apparatus such as a portable computer equipped with the circuit module.

2. Description of the Related Art

Multi-layered printed wiring boards are widely used in electronic apparatuses such as portable computers to achieve high packaging density of circuit components. The multi-layered printed wiring board includes a multi-layered substrate made by alternately stacking conductor layers and insulating layers. The multi-layered substrate has a packaging surface to mount circuit components, and a plurality of pads is placed on the packaging surface.

Pads are to be soldered to connection terminals of the circuit component, and are made a size larger than the connection terminals. Each pad is electrically connected to the conductor layer of the multi-layered substrate by an external signal line or a via hole. Thus, each pad on the packaging surface is electrically connected to each circuit component to be respondent to one electric signal, power supply or ground.

However, in the multi-layered printed wiring board, one pad can electrically handle only one kind of circuit. Thus, when a plurality of pads is densely placed on the packaging surface, there arises a possibility of failing to take space on the packaging surface to make the via hole or to lay the external signal line.

Moreover, the pad requires a certain size to ensure the space for soldering the connection terminal. Therefore, the space occupied by the pad becomes relatively large on the packaging surface, and this disturbs achievement of high packaging density in the multi-layered printed wiring board.

### BRIEF SUMMARY OF THE INVENTION

It is an object of the present invention to provide a printed wiring board which permits using the space of one pad for wiring another electrically different circuit.

It is another object of the invention is to provide a circuit module which enables high density packaging of circuit components.

It is still another object of the invention is to proved an electronic apparatus contained in a thin compact housing.

In order to achieve the first-mentioned object, a printed wiring board of the present invention comprises a substrate having a packaging surface, and a pad placed on the packaging surface of the substrate. The pad has an area to solder a circuit component. A connection part is provided in this area. The connection part is electrically insulated from the pad, and connected to another circuit electrically different from the pad.

It is possible with this structure to use the area of one pad to provide another circuit electrically different from the circuit component. This increases the wiring density of the printed wiring board.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the embodiments given below, serve to explain the principles of the invention.

FIG. 1 is a perspective view of a portable computer according to a first embodiment of the present invention;

FIG. 2 is a sectional view of the portable computer of the first embodiment of the invention, showing a circuit module contained in a housing;

FIG. 3 is a sectional view of the circuit module of the first embodiment of the invention, showing a bare chip soldered to a multi-layered printed wiring board;

FIG. 4 is a magnified sectional view of the part X of FIG. 3;

FIG. 5 is a sectional view taken along the line F5-F5 of FIG. 3;

FIG. 6 is a plane view of the circuit module of the first embodiment of the invention, showing the positional relationship between a pad and a via hole;

FIG. 7 is a sectional view of a circuit module of a second embodiment of the present invention, showing the positional relationship between the pad and the conductive pattern;

FIG. 8 is a plane view of the circuit module of the second embodiment of the invention, showing the positional relationship between the pad and the conductive pattern;

FIG. 9 is a sectional view of a circuit module of a third embodiment of the present invention, showing the positional relationship between a pad and a conductive pattern; and

FIG. 10 is a plane view of the circuit module of the third embodiment of the invention, showing the positional relationship between the pad and the conductive pattern.

### DETAILED DESCRIPTION OF THE INVENTION

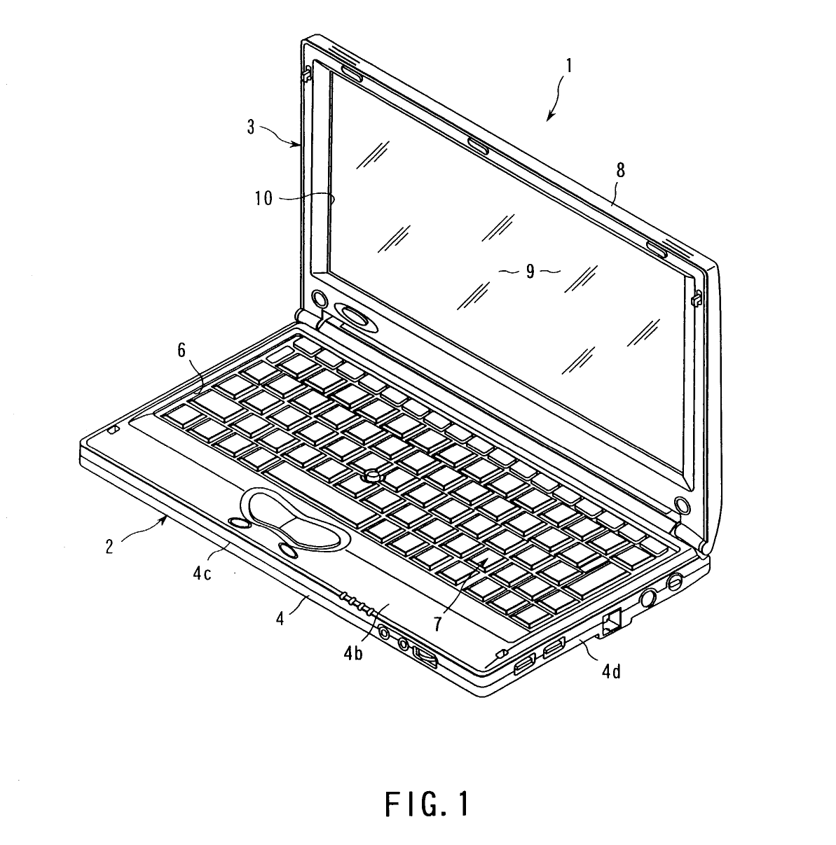

Hereinafter a first embodiment of the present invention will be explained with reference to FIG. 1 to FIG. 6.

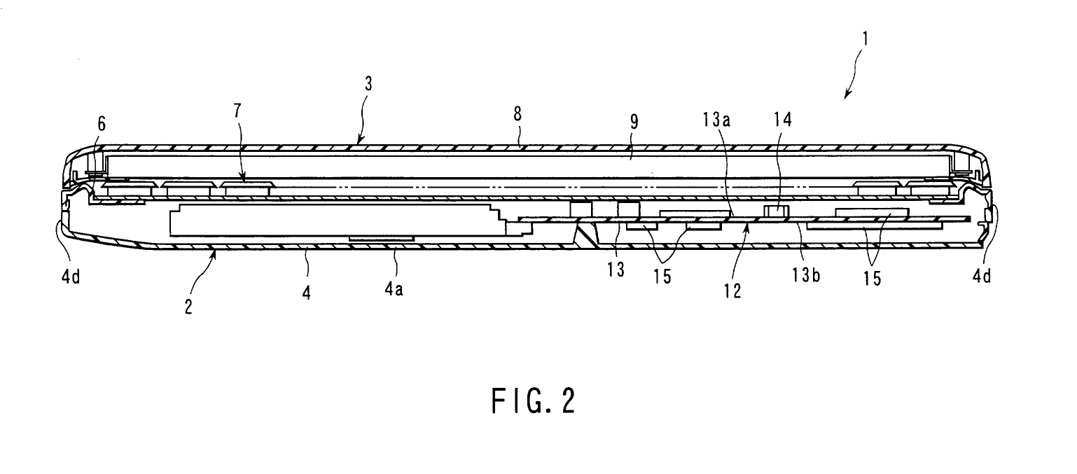

FIG. 1 and FIG. 2 show a portable computer 1 as an electronic apparatus. The portable computer 1 includes a main body 2 and a display unit 3 supported by the main body 2.

The main body 2 comprises a flat box-shaped housing 4. The housing 4 has a bottom wall 4a, a top wall 4b, a front wall 4c and left/right side walls 4d. The top wall 4b has a keyboard mounting section 6. A keyboard 7 is mounted in the keyboard mounting section.

The display unit 3 includes a display housing 8 and a liquid crystal display panel 9 contained in the display housing 8. The display housing 8 is supported by the rear end of the housing 4 through a hinge (not shown). The liquid crystal display 9 is exposed outside through an opening 10 on the front of the display housing 8.

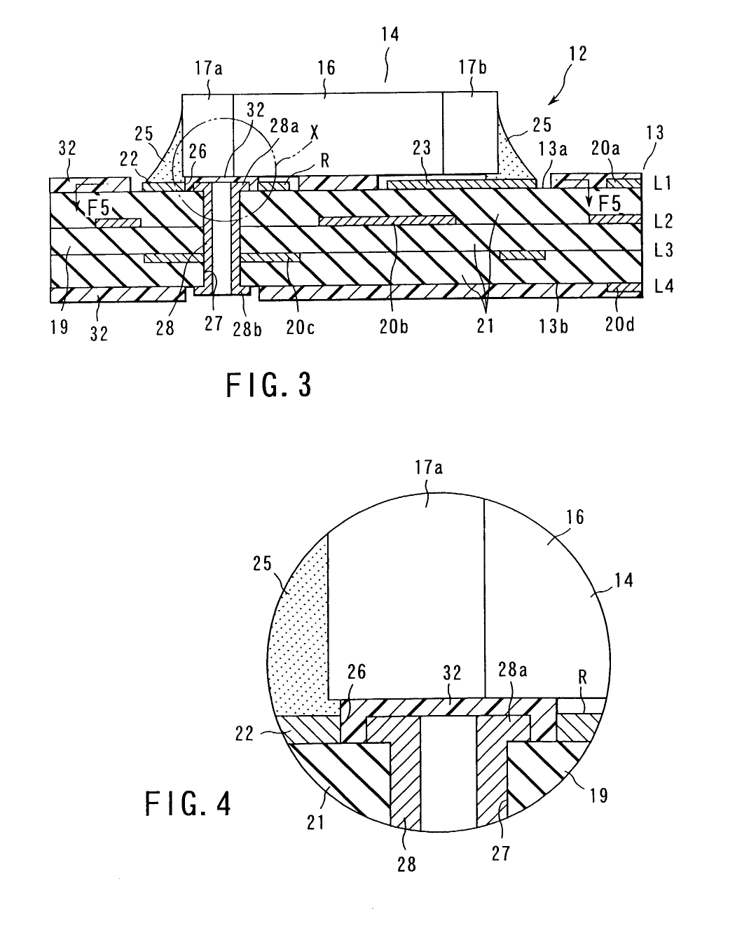

As shown in FIG. 2 and FIG. 3, the housing 4 of the main body 2 contains a circuit module 12. The circuit module 12 includes a multi-layered printed wiring board 13 and a plurality of surface mount circuit components 15. The multi-layered printed wiring board 13 is arranged parallel to the bottom wall 4a of the housing 4. The multi-layered wiring board 13 has a first packaging surface 13a and a second packaging surface 13b. The second packaging surface 13b is on the opposite side of the first packaging surface 13a.

The circuit components 15 are mounted on the first and second packaging surfaces 13a and 13b of the multi-layered printed wiring board 13. The circuit components 15 include a bare chip 14 mounted on the first packaging surface 13a. The bare chip 14 comprises a chip body 16 and a pair of connection terminals 17a and 17b, as shown in FIG. 3. One connection terminal 17a is located at one end of the chip body 16. The other connection terminal 17b is located at the other end of the chip body 16.

As shown in FIG. 3, the multi-layered printed wiring board 13 consists of a multi-layered substrate 19 having four layers, for example. The multi-layered substrate 19 comprises four layers L1 to L4 or first to fourth conductor layers 20a to 20d, and a plurality of insulating layers 21. The first to fourth conductor layers 20a to 20d and the insulating layers 21 are alternately piled up in the thickness direction of the multi-layered substrate 19.

The first to fourth conductor layers 20a to 20d are made of copper foil, for example. The first conductor layer 20a or L1 is formed on the first packaging surface 13a of the multi-layered substrate 19. The fourth conductor 20d or L4 is formed on the second packaging surface 13b of the multi-layered substrate 19. These first and fourth conductor layers 20a and 20d are made linear according to predetermined patterns. The second conductor layer 20b or L2 and third conductor layer 20c or L3 are formed inside the multi-layered substrate 19. These second and third conductor layers 20b and 20c are also made linear according to predetermined patterns.

The insulating layers 21 are made of synthetic resin such as polyamide or epoxy resin, for example. The insulating layers 21 cover the whole conductor layers 20b and 20c.

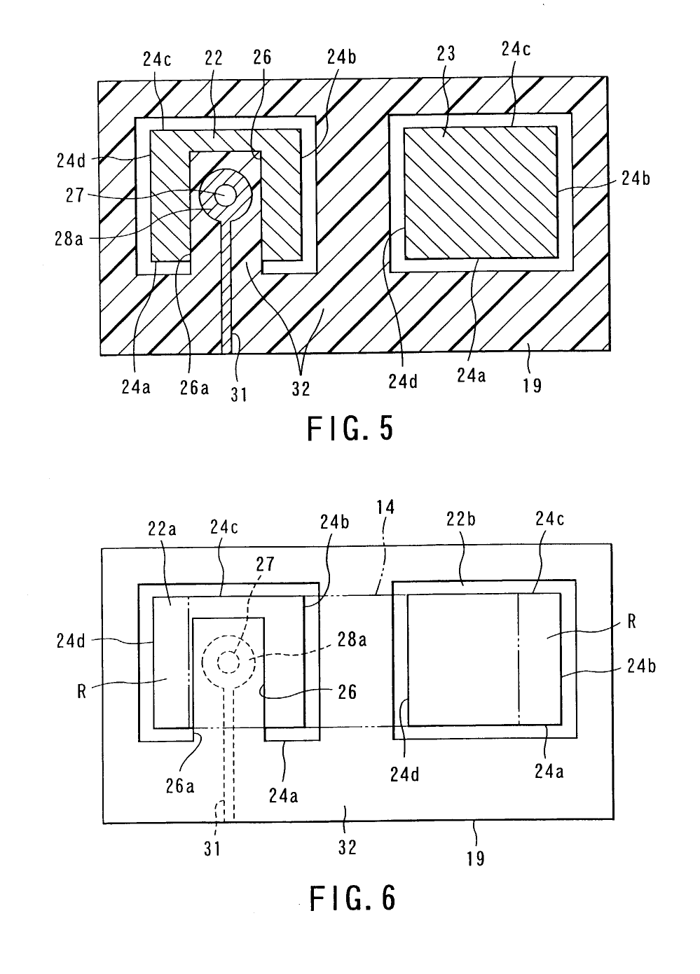

Referring now to FIG. 3, FIG. 5 and FIG. 6, a pair of square pads 22 and 23 are placed on the first packaging surface 13a. These pads 22 and 23 are in parallel to each other with a certain space therebetween. Each pad has first to fourth edges 24a to 24d. These edges 24a to 24d define the area R where the connection terminals 17a and 17b of the bare chip 14 are piled up on the pads 22 and 23, respectively. The area R is a size larger than the connection terminals 17a and 17b. The connection terminals 17a and 17b are soldered to the areas R of the pad 22 and 23, respectively. Thus, a solder fillets 25 are formed extending over the connection terminals 17a and 17b and pads 22 and 23.

The pad 22 has an escape portion 26, as shown in FIG. 5. The escape portion 26 is the shaped as if cutting off the central portion of the pad 22, and has an opening 26a reaching the first edge 24a. The first packaging surface 13a of the multi-layered substrate 19 is exposed in the escape 26.

The multi-layered substrate 19 has a via hole 27 at the position corresponding to the pad 22, as shown in FIG. 3. The via hole 27 penetrates all insulating layers 21 and the third conductor layer 20c of the multi-layered substrate 19, and opens onto the first and second packaging surfaces 13a and 13b. Thus, the third conductor layer 20c is exposed to the inside of the via hole 27.

The inner surface of the via hole 27 is covered by a conductive plating layer 28. The plating layer 28 is in contact with the third conductor layer 20c in the via hole 27 whereby the plating layer 28 is electrically connected to the conductor layer 20c. Further, the plating layer 28 has a pair of lands 28a and 28b as connection areas. One land 28a is exposed to the packaging surface 13a of the multi-layered substrate 19, while the other land 28b is exposed to the packaging surface 13b of the multi-layered substrate 19. The land 28a is brought into the escape portion 26 of the pad 22, and located within the area R of the pad 22. In other words, the escape portion 26 of the pad 22 is cut off as if avoiding the land 28a, and separated from the edge of the land 28a, whereby the land 28a and pad 22 are held electrically insulated.

The land 28a is electrically connected to an external signal line 31 provided on the first packaging surface 31a of the multi-layered substrate 19, as shown in FIG. 5 and FIG. 6. The external signal line 31 is brought out of the pad 22 through the opening 26a of the escape portion 26, and electrically connected to the first conductor 20a or the first layer L1 of the multi-layered substrate 19. Thus, the plating layer 28 of the via hole 27 makes electrical connection between the first conductor layer 20a and the third conductor layer 20c, thereby constituting another circuit electrically different from the pad 22.

Referring again to FIG. 3 and FIG. 4, the first and second packaging surfaces 13a and 13b are covered by solder resists 32 except for the pads 22 and 23. A part of the solder resist 32 on the first packaging surface 13a is interposed between the land 28a and the connection terminal 17a, and another part thereof is interposed between the edge of the land 28a and the escape portion 26 of the pad 22. As a result, the solder resist 32 on the first packaging surface 13a covers the land 28a and external signal line 31. Therefore, the land 28a, the pad 22 and the connection terminal 17 of the bare chip 14 are held electrically insulated to one another.

In this structure, the pad 22 of the printed wiring board 13 has the escape portion 26 like a cut-off to open at the edge 24a, and the via hole 27 having the plating layer 28 for connecting layers can be made at the position corresponding to the escape portion 26.

Therefore, it is possible to electrically connect the first conductor layer 20a and third conductor layer 20c by utilizing the area R of the pad 22 where the connection terminal 17a of the bare chip 14 is soldered. Even if the area occupied by the pad 22 is large in the first packaging surface 13a, the pad 22 will not disturb the making of the via hole 27 or the laying of the external signal line 31. This simplifies the wiring design of the multi-layered wiring board 13, and greatly increases the wiring density of the multi-layered printed wiring board 13.

Moreover, the increased wiring density of the multi-layered printed wiring board 13 reduces the size of a printed wiring board 13. This will meet the tendency of increasing the number of terminals resulting from multiple functions given to the circuit component 15, and deal with the increased packing density of the circuit component 15 and bare chip 14. This makes it possible to miniaturize the circuit module 12 and reduce the size of the housing 4 to contain the circuit module 12, and advantageous to achieve compactness of the portable computer 1.

The via hole is made in the area of one pad in the first embodiment, but it is replaceable by a blind via hole.

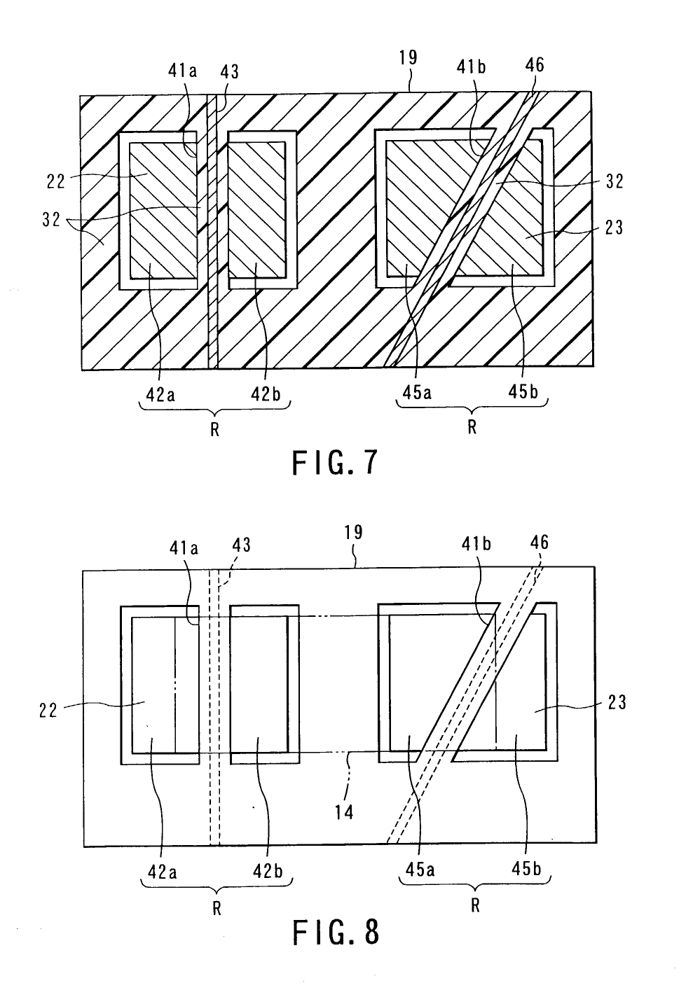

The present invention is not restricted to the first embodiment. A second embodiment is shown in FIG. 7 and FIG. 8.

In the second embodiment, a pair of pads 22 and 23 to solder the bare chip 14 has straight slit-like escape portions 41a and 41b, respectively. The escape portion 41a divides the area R of the pad 22 into two soldering sections 42a and 42b. These soldering sections 42a and 42b are electrically connected to the first conductor layer 20a of the multi-layered substrate 19. The soldering sections 42a and 42b face each other interposing the escape portion 41a therebetween. A first conductive pattern 43 is provided as a connection part in the escape portion 41a.

The first conductive pattern 43 constitutes a circuit electrically different from the first conductor layer 20a connected to the pad 22. The first conductive pattern 43 is separated from the soldering sections 42a and 42b, thereby being electrically insulated from the pad 22.

The escape portion 41b divides the area R of the pad 23 into two soldering sections 45a and 45b. These soldering sections 45a and 45b are electrically connected to the first conductor layer 20a of the multi-layered substrate 19. The soldering section 45a and 45b face each other interposing the escape portion 41b therebetween. A second conductive pattern 46 is provided as a connection part in the escape portion 41b.

The second conductive pattern 46 constitutes another circuit electrically different from the first conductor layer 20a connected to the pad 23. The second conductive pattern 46 is separated from the soldering sections 45a and 45b, thereby being electrically insulated from the pad 23.

The solder resist 32 covering the first packaging surface 13a of the multi-layered substrate 19 goes into the escape portions 41a and 41b, and cover the first and second conductive patterns 43 and 46. Thus, the pads 22 and 23 and the first and second conductive patterns 43 and 46 are held so as to be electrically insulated by the solder resist 32.

With this structure, the first and second conductive patterns 43 and 46 can be placed by utilizing the area R of the pads 22 and 23, respectively, to which the connection terminals 17a and 17b of the bare chip 14 are soldered. Thus, it is unnecessary to route the first and second conductive patterns 43 and 46 around the pads 22 and 23 when providing the first and second conductive patterns 43 and 46 on the first packaging surface 13 of the multi-layered substrate 19. This facilitates the wiring design of the multi-layered printed wiring board 13. Further, the wiring length of the conductive patterns 43 and 46 can be reduced, and this is particularly convenient for making a high-speed circuit which handles high-speed transmission signals.

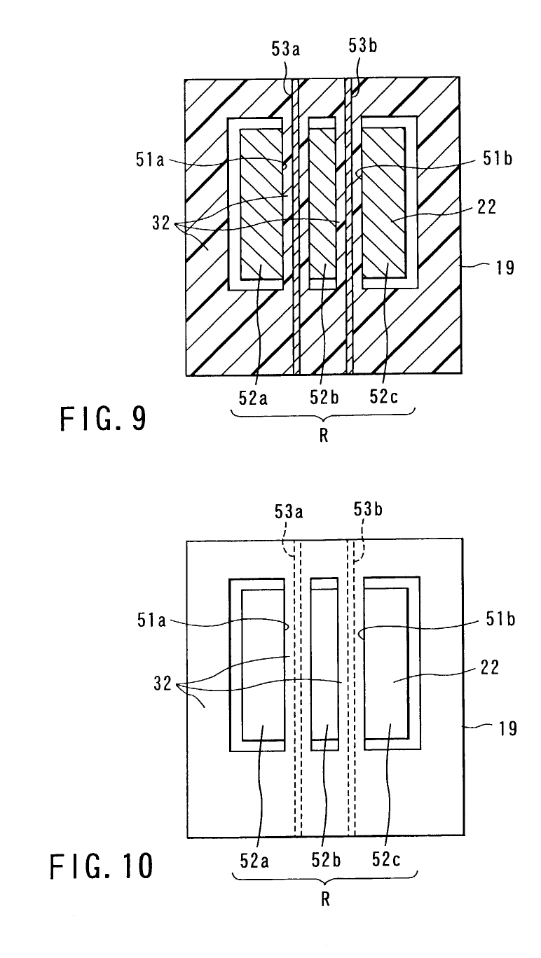

Description will now be given to a third embodiment of the invention with reference to FIG. 9 and FIG. 10.

In the third embodiment, one pad 22 has a pair of straight slit-like escape portions 51a and 51b. These escape portions 51a and 51b are in parallel to each other with a certain space taken therebetween, and divide the area R of the pad 22 into three soldering sections 52a, 52b, 52c. The soldering sections 52a, 52b, 52c are electrically connected to the first conductor layer 20a of the multi-layered substrate 19.

First and second conductive patterns 53a and 53b are provided as connection parts in the escape portions 51a and 52b of the pad 22. These conductive patterns 53a and 53b constitute a circuit electrically different from the first conductor layer 20a connected to the pad 22. The first and second conductive patterns 53a and 53b are separated from the soldering sections 52a, 52b, 52c, thereby electrically insulated from the soldering sections 52a, 52b, 52c.

The solder resist 32 covering the first packaging surface 13a of the multi-layered substrate 19 goes into the escape portions 51a and 51b, covering the first and second conductive patterns 53a and 53b. Thus, the pad 22 and the first and second conductive patterns 53a and 53b are held so as to be electrically insulated by the solder resist 32.

With this structure, the first and second conductive patterns 53a and 53b can be provided in the area R of one pad 22, increasing the wiring density of the multi-layered printed wiring board 13.

The printed wiring board according to the present invention is not restricted to a multi-layered printed wiring board with a plurality of alternately stacked conductor layers and insulating layers. The invention may be embodied in other forms, for example, a single-sided printed wiring board with a conductor layer formed only on one side of an insulating layer, or a double-sided printed wiring board with a conductor layer formed on both front and back sides of an insulating layer.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A printed wiring board comprising:
a substrate having a packaging surface;
a pad placed on said packaging surface of said substrate, said pad having an area to solder a circuit component; and
a connection part provided in the area of said pad, said connection part electrically insulated from said pad and connected to a circuit electrically different from said pad.

2. A printed wiring board according to claim 1, wherein said packaging surface of said substrate is covered by a solder resist except for the part corresponding to said pad.

3. A printed wiring board according to claim 2, wherein said pad has an escape portion to avoid said connection part, and said solder resist covers said connection part and interposed between said escape portion and said connection part.

4. A printed wiring board according to claim 3, wherein said pad has edges defining said area, and said escape portion has an opening connected to one of said edges.

5. A printed wiring board according to claim 1, wherein said substrate includes a conductor layer formed on said packaging surface, and said connection part is electrically connected to said conductor layer.

6. A printed wiring board according to claim 1, wherein said substrate comprises a plurality of conductor layers, a plurality of insulating layers to electrically insulate said conductor layers to one another, and a via hole penetrating at least one said conductor layer and said dielectric layers; said via hole includes a plating layer electrically connecting said conductor layers; and said plating layer has a land which is exposed to the packaging surface of said substrate and functions as said connection part.

7. A printed wiring board according to claim 1, wherein said connection part includes at least one conductive pattern provided on said packaging surface of said substrate, said conductive pattern crossing and dividing said pad.

8. A printed wiring board according to claim 6, wherein said pad has a slit-like escape portion to pass said conductive pattern, said escape dividing said pad into a plurality of electrically insulated sections.

9. A printed wiring board comprising:
a multi-layered substrate having a packaging surface, said multi-layered substrate comprising a plurality of conductor layers, a plurality of insulating layers to electrically insulate said conductor layers to one another and a via hole penetrating at least one said conductor layer and said insulating layers, said via hole having a plating layer to electrically connect said conductor layers, said plating layer having a land exposed to said packaging surface; and
a pad placed on said packaging surface of said multi-layered substrate, said pad including an area to solder a circuit component, said area having an escape portion to avoid said land, and said escape portion being electrically insulated from said land.

10. A printed wiring board according to claim 9, wherein said land is covered by a solder resist, and a part of said solder resist is interposed between said escape portion and said land.

11. A printed wiring board according to claim 9, wherein said land is connected to a circuit electrically different from said pad.

12. A circuit module comprising:
a circuit component; and
a printed wiring board having a packaging surface to mount said circuit component, said printed wiring board including a pad having an area to solder said circuit component and at least one connection part provided in said area of said pad, said connection part being electrically insulated from said pad and connected to a circuit electrically different from said pad.

13. A circuit module according to claim 12, wherein said pad has an escape portion cut off just like avoiding said connection part; the packaging surface of said printed wiring board is covered by a solder resist except for the part corresponding to said pad; and said solder resist covers said connection part and is placed between said escape portion and said connection part.

14. A circuit module according to claim 12, wherein said printed wiring board includes a plurality of conductor layers, a plurality of insulating layers to electrically insulate said conductor layers to one another and a via hole penetrating at least one said conductor layer and said dielectric layers; said via hole has a plating layer to electrically connect said conductor layers; and said plating layer has a land which is exposed to said packaging surface of said printed wiring board and functions as said connection part.

15. An electronic apparatus comprising:
a housing; and
a printed wiring board contained in said housing, having a packaging surface to mount a circuit component, said printed wiring board including a pad having an area to solder said circuit component and at least one connection part provided in said area of said pad, and said connection part being electrically insulated from said pad and connected to a circuit electrically different from said pad.

16. An electronic apparatus according to claim 15, wherein said printed wiring board includes a plurality of conductor layers, a plurality of insulating layers to electrically insulate said conductor layers to one another and a via hole penetrating at least one said conductor layer and said dielectric layers; said via hole has a plating layer to electrically connect said conductor layers; and said plating layer has a land which is exposed to said packaging surface of said printed wiring board and functions as said connection part.
